(19) United States
(12) Patent Application Publication
(10) Pub. No.: US 2010/0167535 A1
(43) Pub. Date: Jul. 1, 2010

(54) CLEANING AGENT FOR SEMICONDUCTOR DEVICE AND METHOD FOR PRODUCING SEMICONDUCTOR DEVICE USING THE CLEANING AGENT

(75) Inventors: Yoshinori NISHIWAKI, Shizuoka-ken (JP); Tomonori TAKAHASHI, Shizuoka-ken (JP); Kazutaka TAKAHASHI, Shizuoka-ken (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/642,882

(22) Filed: Dec. 21, 2009

(30) Foreign Application Priority Data
Dec. 26, 2008 (JP) 2008-334603
Mar. 30, 2009 (JP) 2009-083047

(51) Int. Cl. H01L 21/321; C11D 7/26; C11D 7/32

(52) U.S. Cl. 438/669; 510/175; 438/692; 257/E21.304

(57) ABSTRACT

A cleaning agent used after chemical mechanical polishing of a semiconductor device, the cleaning agent including a polycarboxylic acid and diethylenetriamine pentaacetic acid, the semiconductor device including a copper diffusion barrier film and copper wiring on an interlayer dielectric film, and the dielectric film containing SiOC and having a dielectric constant of 3.0 or less.

### CROSS-REFERENCE TO RELATED APPLICATION

This application claims priority under 35 USC 119 from Japanese Patent Application No. 2008-334603 filed on Dec. 26, 2008 and Japanese Patent Application No. 2009-083047 filed on Mar. 30, 2009, the disclosures of which are incorporated by reference herein.

### BACKGROUND OF THE INVENTION

1. Field of the Invention

The invention relates to a cleaning agent used in a cleaning process of a semiconductor device after a planarization process by chemical mechanical polishing (referred to hereinafter as “CMP”) in a production process of a semiconductor device, and to a process for producing a semiconductor device by using the cleaning agent.

2. Description of the Related Art

In a process for producing semiconductor devices such as microprocessors, memories or CCDs and for producing flat panel display devices such as TFT liquid crystals, a pattern of about 10 to 100 nm or a thin film is formed on a surface of a substrate such as silicon, silicon oxide (SiO₂) or glass. In each process of the production, reduction of traces of contamination at the substrate surface is very important.

Contamination of the substrate surface includes in particular, particle contamination, organic contamination and metal contamination, which must be reduced as much as possible before conducting the next step, since such contamination may cause failure in device electrical characteristics, or a reduction in the fabrication yield of devices. To remove contamination, cleaning of a substrate surface with a cleaning liquid is generally conducted. However, when a highly reactive compound is used in order to achieve sufficient cleaning performance, corrosion of copper wiring is caused and the reliability of the device is decreased. Accordingly, there is a need to clean a surface to a high degree and reproducibly in a short time at low cost and without adverse affects. In recent years, such demand has been greatly increased together with increased integration and decreasing costs of devices.

In the production of semiconductor devices such as semiconductor integrated circuits (hereinafter, referred to as LSI), a multilayered structure is formed in which an interlayer dielectric film and/or a metal film are layered on a substrate. In recent years, in order to increase speed and integration, a new metal material (Cu or the like) having a low resistance is used as wiring, and a low dielectric constant (low-k) material is used as an interlayer dielectric film. In general, a process has been conducted in which an interlayer dielectric film (ILD film) such as an interlayer dielectric film having a dielectric constant of as low as 3.5 to 2.0 (for example, an organic polymer film, a silica film containing a methyl group, a silica film containing H—Si, an SiOF film, a porous silica film, or a porous organic film) and a metal film such as copper used in wiring have been deposited, the resulting uneven surface is subjected to planarization treatment by CMP, and then other wiring has been disposed on the planarized surface.

In the cleaning step between processes, an RCA cleaning agent in which an acidic or alkaline solution and hydrogen peroxide is mixed has been used. However, this cleaning agent dissolves copper in wiring in addition to a passive-state copper oxide attached to an interlayer dielectric film which should be removed. Therefore, this cleaning agent is unfavorable since the corrosion and disconnection of the wiring may be caused. Furthermore, many low-k interlayer dielectric films are hydrophobic on their surface and thus repel the cleaning liquid, thereby reducing cleaning performance. In a post CMP cleaning process, slurry (polishing particles) used in the CMP process remains on the surface of wiring or low-k interlayer dielectric films, which causes contamination.

When semiconductor devices such as LSIs are produced, a layered structure of a barrier metal such as of Ta, TaN, Ti, TiN or Ru is pre-formed in order to prevent diffusion of the wiring material into an interlayer dielectric film. In recent years, in order to increase speed and integration of devices, application of a self-formed barrier material such as Mn, which is formed by heat diffusion, has been noticed as a new barrier metal material. However, when using such a self-formed barrier material, a copper oxide is easily formed between copper in wiring and the barrier metal, and corrosion with a solution for dissolving the copper oxide in the cleaning process has become a new problem.

When a porous dielectric film such as a low dielectric porous silica film or a porous organic film is used, once the dielectric film is damaged by polishing, water may penetrate into the interlayer dielectric film after the polishing process and thus copper oxide may be easily formed between the interlayer dielectric film and wiring. As a result, a further problem may occur in that the formed copper oxide may be dissolved when subjected to a cleaning step with a conventional cleaning agent.

In order to remove particles attached to and remaining on the surface of a semiconductor device after the CMP process, it is generally thought that an alkaline cleaning agent is effective, since particles and the surface of the semiconductor are electrostatically repelled. For example, a cleaning agent containing a specific surfactant and an alkaline or organic acid has been proposed (see, for example, Japanese Patent Application Laid-Open (JP-A) No. 2003-289060). However, further improvement of this cleaning agent has been desired in order to efficiently remove a metal derived from a material to be polished, a substrate material, organic residues and fine abrasive particles attached to the surface of a substrate.

In consideration of efficient removal of organic residues and fine abrasive particles, an acidic cleaning liquid containing a specific organic acid and a surfactant has been disclosed (see, for example, JP-A No. 10-72594). In this cleaning liquid, however, further improvement has been desired in order to efficiently remove contaminants on a surface of a semiconductor device provided with a hydrophobic low-k interlayer dielectric film and copper wiring, while preventing corrosion and oxidization of the copper wiring.

From the viewpoint described above, a cleaning agent to which a material having a corrosion-preventing effect, such as benzotriazole, has been added to reduce the erosion of copper wiring has also been proposed (see, for example, JP-A No. 2005-307187). However, this cleaning agent is not so preferable in consideration of removal of contaminants such as residues and of influence on a protective film remaining on the surface of copper. Further, a two-step cleaning method using a first cleaning liquid containing ammonia and a second cleaning liquid containing a complex agent or a surfactant has been proposed (see, for example, JP-A 2000-91277) However, the two-step cleaning method consists of complicated two steps is complicated, and requires an improvement in suppression of corrosion of metal.

Under such circumstances, a cleaning agent which can effectively remove contaminants on the surface of a semiconductor device having a hydrophobic low-k interlayer dielectric film or copper wiring thereon, while preventing corrosion or oxidation of copper wiring, has been required.

### SUMMARY OF THE INVENTION

The present invention provides a cleaning agent that can produce a highly clean surface of a substrate and can remove organic contamination and particle contamination of the surface of a semiconductor device, while preventing corrosion of copper wiring, when used in a cleaning process after a planarization polishing process in producing the semiconductor device, particularly in a semiconductor device that has a low-k interlayer dielectric film including SiOC and having a dielectric constant of 3.0 or less and copper wiring on the surface of the interlayer dielectric film. In addition, the present invention provides a method of manufacturing a semiconductor device having a highly clean surface, from which contaminants after a planarization process are removed, while preventing corrosion of copper wiring by using the cleaning agent for semiconductor devices described above.

As a result of extensive study of cleaning agents used in the post-CMP process by the inventors, it has been found that the problem can be solved by using a cleaning agent containing a polycarboxylic acid and diethylenetriamine pentaacetic acid (DTPA).

The present invention includes the following aspects:

<1> A cleaning agent used after chemical mechanical polishing of a semiconductor device, the cleaning agent including a polycarboxylic acid and diethylenetriamine pentaacetic acid, the semiconductor device includes a copper diffusion barrier film and copper wiring on an interlayer dielectric film, and the dielectric film contains SiOC and has a dielectric constant of 3.0 or less.

<2> The cleaning agent according to <1>, wherein the content of the polycarboxylic acid in the cleaning agent is from 0.05 g/L to 300 g/L with respect to the total mass of the cleaning agent.

<3> The cleaning agent according to <1>, wherein the content of the diethylenetriamine pentaacetic acid in the cleaning agent is from 0.00001 g/L to 50 g/L with respect to the total mass of the cleaning agent.

<4> The cleaning agent according to <1>, wherein the copper diffusion barrier film includes manganese.

<5> The cleaning agent according to <4>, wherein the copper diffusion barrier film includes a self-formed manganese layer.

<6> The cleaning agent according to <1>, wherein the copper diffusion barrier film includes at least one selected from Ti, TiN, Ta, TaN or Ru.

<7> The cleaning agent according to <1>, wherein the polycarboxylic acid is at least one selected from the group consisting of oxalic acid, citric acid, maleic acid, malic acid and tartaric acid.

<8> The cleaning agent according to any one of <1> to <7>, which has a pH value of 1 to 5.

<9> The cleaning agent according to any one of <1> to <8>, further including at least one surfactant selected from an anionic surfactant or a nonionic surfactant.

<10> A method for producing a semiconductor device including:

forming an interlayer dielectric film containing SiOC and having a dielectric constant of 3.0 or less;

forming a copper diffusion barrier film on the interlayer dielectric film;

forming copper wiring on the copper diffusion barrier film to form a multilayer structure having the wiring thereon;

forming a semiconductor device by chemical mechanical polishing of the surface of the multilayer structure having the wiring thereon with a metal-polishing liquid containing abrasive particles and an oxidizing agent; and

cleaning the surface of the semiconductor device with the cleaning agent of any one of <1> to <9>.

<11> A method for producing a semiconductor device including:

forming an interlayer dielectric film containing SiOC and having a dielectric constant of 3.0 or less;

forming wiring containing copper and manganese on the interlayer dielectric film;

heating the wiring containing copper and manganese to accumulate the manganese to a surface of the wiring and forming a self-formed manganese layer, thereby forming a multilayer structure having a copper diffusion barrier film thereon;

forming a semiconductor device by chemical mechanical polishing of the surface of the multilayer structure having a copper diffusion barrier film thereon with a metal-polishing liquid containing abrasive particles and an oxidizing agent; and

cleaning the surface of the semiconductor device with the cleaning agent of any one of <1> to <9>.

The semiconductor device to be cleaned with the cleaning agent of the present invention is a substrate that has been subjected to a chemical mechanical polishing process in a semiconductor device production process. The substrate may be a monolayer substrate having metal wiring on a surface thereof, or may be a multilayer wiring substrate having wiring on an interlayer dielectric film formed on a surface of the substrate.

In particular, the cleaning agent of the invention is useful for cleaning substrates for semiconductor devices having metal wiring and a porous low dielectric constant (low-k) film on a part or the whole of the surface thereof. In the invention, an interlayer dielectric film having a dielectric constant of 3.0 or less is sometimes referred to as a “low-k film”, while an interlayer dielectric film having a minute hole and having a dielectric constant of 2.7 or less is sometimes referred to as a “porous low-k film”.

The mechanism of the cleaning agent of the invention is unknown, but is thought to be as follows.

When a cleaning agent containing a passive film-forming agent such as a polycarboxylic acid or BTA is used as an additive to the cleaning agent used in a post-CMP process, it is expected that the surface of a semiconductor device having a hydrophobic low-k interlayer dielectric film or copper wiring is effectively cleaned, while preventing erosion or oxidization of copper wiring.

In recent years, with the miniaturization of wiring and the application of various barrier metal species or porous low-k interlayer dielectric films, there has been a desire to obtain the two effects of reducing corrosion caused by dissolution of copper oxide formed in a copper wiring and improving cleaning performance. When using a conventional passive film-forming agent such as benzotriazole (BTA), a component of the passive film-forming agent remains at the surface of copper wiring. Further, when an organic acid is used in combination with a surfactant, the effects of reducing corrosion and improving cleaning performance cannot be simultaneously achieved. In particular, there are further concerns that when a substrate having a low-k film is used, oxidation and corrosion of copper wiring caused by penetration of water or other components into minute holes of the low-k film may occur, and thus higher corrosion preventing performance is required.

On the other hand, the cleaning agent of the present invention includes a polycarboxylic acid as an organic acid and diethylenetriamine pentaacetic acid (DTPA), in place of the passive film-forming agent. In the cleaning agent of the present invention, different from a conventional corrosion preventing agent such as BTA or the like, DTPA functions as a corrosion preventing compound, and exhibits a sufficient corrosion preventing performance and an excellent performance for removing organic residues when used in combination with a polycarboxylic acid. In addition, DTPA is less likely to retain on the surface of copper wiring is prevented, and is removed rapidly from the surface of the substrate by washing with water after cleaning. Therefore, low corrosion and higher cleaning performance can be achieved with the cleaning agent of the present invention.

According to the present invention, there is provided a cleaning agent that can produce a highly clean surface of a substrate and can remove organic contamination and particle contamination of the surface of a semiconductor device, while preventing corrosion of copper wiring, when used in a cleaning process after a planarization polishing process in producing the semiconductor device, particularly in a semiconductor device that has a low-k interlayer dielectric film including SiOC and having a dielectric constant of 3.0 or less and copper wiring on the surface of the interlayer dielectric film.

In addition, the present invention provides a method of manufacturing a semiconductor device having a highly clean surface, from which contaminants after a planarization process are removed while preventing corrosion of copper wiring, by using the cleaning agent for semiconductor devices described above.

### DETAILED DESCRIPTION OF THE INVENTION

Hereinafter, exemplary embodiments of the present invention will be described.

Cleaning Agent

The cleaning agent of the present invention includes a polycarboxylic acid and diethylenetriamine pentaacetic acid (hereinafter, sometimes referred to as DTPA), and is preferably used in the cleaning of the surface of a semiconductor device, particularly a device having copper wiring on the surface thereof, in a post-chemical mechanical polishing process of a semiconductor device manufacturing process. The sufficient effect can be obtained when the cleaning agent of the invention is used for a semiconductor device including a copper diffusion barrier film and copper wiring on a surface of an interlayer dielectric film that includes SiOC and has a dielectric constant of 3.0 or less.

Hereinafter, the respective components of the cleaning agent of the present invention will be described.

Diethylenetriamine Pentaacetic Acid

The cleaning agent of the present invention includes diethylenetriamine pentaacetic acid (DTPA). DTPA can act as a corrosion preventing compound in the cleaning agent and inhibit the corrosion of copper wiring during cleaning. In addition, adsorption and retention of DTPA on copper wiring can be prevented due to its structure, and thus removed rapidly after cleaning.

The content of DTPA in the cleaning agent of the invention is from 0.00001 g/L to 50 g/L, preferably from 0.0001 g/L to 40 g/L, more preferably from 0.001 g/L to 30 g/L, and even more preferably from 0.01 g/L to 20 g/L, with respect to the total mass of the cleaning agent.

When the content of DTPA is within the above range, copper wiring may not deteriorate, and organic contamination and particle contamination may be removed in a short time, whereby a surface of a substrate may be cleaned to a high degree.

Polycarboxylic Acid

The cleaning agent of the present invention includes a polycarboxylic acid. The polycarboxylic acid can improve performance for removing metallic contaminants and metal complexes.

Any polycarboxylic acid may be used as the polycarboxylic acid of the invention, as long as it is a compound having at least two carboxy groups in a molecule or a salt thereof. The polycarboxylic acid of the invention preferably a compound having 2 to 8 carboxy groups in a molecule or a salt thereof, more preferably a compound having 2 to 6 carboxy groups in a molecule or a salt thereof, and even more preferably a compound having 2 to 4 carboxy groups in a molecule or a salt thereof.

Examples of the polycarboxylic acid that can be used in the invention include dicarboxylic acids such as oxalic acid, malonic acid, maleic acid or succinic acid, oxypolycarboxylic acids such as tartaric acid, malic acid or citric acid, and salts thereof.

Among these polycarboxylic acids, oxalic acid, citric acid, malonic acid, maleic acid, malic acid and tartaric acid are preferable, and oxalic acid, citric acid, maleic acid, malic acid and tartaric acid are more preferable, from the viewpoint safety of material, cost and cleaning performance.

In the cleaning agent of the invention, the polycarboxylic acid may be used singly or in combination of two or more kinds thereof at an appropriate ratio.

In order to obtain sufficient cleaning effect and to reduce influence of copper wiring simultaneously, the content of the polycarboxylic acid in the cleaning agent of the invention is preferably from 0.05 g/L to 300 g/L, and more preferably from 0.1 g/L to 100 g/L, with respect to the total mass of the cleaning agent.

Ina addition to the above-described essential components, the cleaning agent of the invention may further include various additives depending on the object, as long as the effect of the invention is not deteriorated. Hereinafter, additives that may be used in the cleaning agent of the invention are described.

Additional Organic Acid

The cleaning agent of the invention may include an additional organic acid in addition to the polycarboxylic acid. The additional organic acid is an organic compound other than the polycarboxylic acid and the organic compound is acidic (pH<7) in water. Examples of the additional organic acid include an organic compound having an acidic functional group such as a carboxy group, a sulfo group, a phenolic hydroxyl group or a mercapto group.

When the additional organic acid is used, the content thereof is preferably equal to or less than the content of the above-described polycarboxylic acid.

Surfactant

The cleaning agent of the invention preferably includes at least one surfactant selected from an anionic surfactant or a nonionic surfactant, from the viewpoint of improvement of wetting properties of a substrate as well as improvement of cleaning performance associated with wetting properties.

The surfactant may be used singly or in combination of two or more kinds thereof. When two or more kinds of surfactants are used in combination, at least one anionic surfactant and at least one nonionic surfactant may be used in combination.

When a cationic surfactant is added to the cleaning agent of the invention, the cationic moiety in the cationic surfactant and the organic acid in the cleaning agent may interact with one another, and therefore may reduce the performance and effect of the organic acid. Accordingly, the surfactant used in the invention is preferably an anionic surfactant, a nonionic surfactant or a combination thereof.

Hereinafter, respective surfactants are described.

Anionic Surfactant

Examples of the anionic surfactant that may be used in the invention include carboxylates, sulfonates, sulfates and phosphates.

Specific examples of the carboxylates include soap, N-acylamino-acid salts, polyoxyethylene/polyoxypropylene alkyl ether carboxylates and acylated peptides.

Specific examples of the sulfonates include alkyl sulfonates, sulfosuccinates, α-olefin sulfonates and N-acylsulfonates.

Specific examples of the sulfates include sulfated oils, alkyl sulfates, alkyl ether sulfates, polyoxyethylene/polyoxypropylene alkyl aryl ether sulfates and alkyl amide sulfates.

Specific examples of the phosphates include alkyl phosphates, polyoxyethylene/polyoxypropylene alkyl aryl ether phosphates.

Preferable examples of the anionic surfactant include those having at least one aliphatic hydrocarbon structure or aromatic ring structure in a molecule. Examples of the aliphatic hydrocarbon structure in the anionic surfactant include a structure having an alkyl group or an alkyl ether group, and is preferably an alkyl group having 1 to 20 carbon atoms or an alkyl ether group having 1 to 30 carbon atoms. Each of the alkyl group and the alkyl ether group may further have a substituent such as an alkynyl group or a hydroxy group.

Examples of the aromatic ring include a benzene ring, a naphthalene ring, an anthracene ring, a tetracene ring, a phenanthrene ring, a chrysene ring and a pyrene ring. Each of these aromatic ring structures may further have a substituent such as an alkyl group.

Preferable examples of the anionic surfactant further include alkyl sulfonic acids and salts thereof, alkyl ether sulfates and salts thereof, alkylbenzene sulfonic acids and salts thereof, alkylnaphthalene sulfonic acids and salts thereof, alkyl diphenylether sulfonic acids and salts thereof, alkyl diphenylether disulfonic acids and salts thereof, a phenol sulfonic acid-formaldehyde condensate and salts thereof, an aryl phenol sulfonic acid-formaldehyde condensate and salts thereof.

The alkyl group as the substituent of the aromatic ring of the anionic surfactants may be a linear alkyl group or a branched alkyl group. The alkyl group is preferably an alkyl group having 2 to 30 carbon atoms, more preferably an alkyl group having 3 to 22 carbon atoms, and examples thereof include a propyl group, a butyl group, a pentyl group, a hexyl group, an octyl group, a nonyl group, a decyl group, a dodecyl group, a hexadecyl group and an octadecyl group.

When the anionic surfactant is a salt, examples of the salt include a sodium salt, a potassium salt, an ammonium salt, a triethanolamine salt and a tetramethyl ammonium salt.

Specific examples of the anionic surfactant include pentadecane sulfonic acid (n=15), decadency ether sulfonic acid (n=12), dodecyl benzene sulfonic acid, dodecyl diphenyl ether disulfonic acid, dodecyl diphenyl ether sulfonic acid, diphenyl ether disulfonic acid, propyl naphthalene sulfonic acid, triisopropyl naphthalene sulfonic acid, and alkali metal salts, ammonium salts and triethanolamine salts thereof.

Examples of the anionic surfactant that may be used in the invention further include a surfactant having at least one substituent such as a polyoxyethylene group, a polyoxypropylene group, a fluoroalkyl group, an acetylene group or a hydroxyl group, in addition to an aliphatic hydrocarbon structure or aromatic hydrocarbon structures in a molecule. Specific examples thereof include a sodium polyoxyethylene alkylene ether sulfate, polyoxyethylene tristyryl phenyl ether phosphate, and a phenol sulfonic acid-formaldehyde condensate.

Among these anionic surfactants, an alkyl sulfonic acid having 15 carbon atoms in average, an alkyl ether sulfate having 10 to 15 carbon atoms, dodecyl benzene sulfonic acid, dodecyl diphenyl ether disulfonic acid, triisopropyl naphthalene sulfonic acid, polyoxyethylene lauryl ether, and polyethylene tristyryl phenyl ether phosphate are preferable.

The anionic surfactant may be a commercial product, and preferable examples thereof include PIONINE A-32-B (alkyl sulfonic acid) (trade name, manufactured by Takemoto Oil & Fat Co., Ltd.), PIONINE A-28-B (sodium polyoxyethylene alkyl (12,13) ether (3EO)sulfate) (trade name, manufactured by Takemoto Oil & Fat Co., Ltd.), PIONINE A-44-TF (triisopropyl naphthalene sulfonic acid) (trade name, manufactured by Takemoto Oil & Fat Co., Ltd.), PELEX NBL (sodium alkyl naphthalene sulfonate) (trade name, manufactured by Kao Corporation), NEOPELEX GS (dodecyl benzene sulfonic acid) (trade name, manufactured by Kao Corporation), NEOPELEX GS-15 (sodium dodecyl benzene sulfonate) (trade name, manufactured by Kao Corporation), PELEX SS-L (sodium alkyl diphenyl ether disulfonate) (trade name, manufactured by Kao Corporation), and DEMOL NL (sodium β-naphthalenesulfonate-formaldehyde condensate) (trade name, manufactured by Kao Corporation).

Nonionic Surfactant

The nonionic surfactant may be an ether nonionic surfactant, an ether/ester nonionic surfactant, an ester nonionic surfactant or a nitrogen-containing nonionic surfactant. Examples of the ether nonionic surfactant include a polyoxyethylene alkyl, an alkyl phenyl ether, an alkyl aryl formaldehyde-condensed polyoxyethylene ether, a polyoxyethylene-polyoxypropylene block polymer, and a polyoxyethylene polyoxypropylene alkyl ether.

Examples of the ether/ester nonionic surfactant include a glyceryl ester of polyoxyethylene ether, a polyoxyethylene ether sorbitan ester, a polyoxyethylene ether sorbitol ester.

Examples of the ester nonionic surfactant include a polyethylene glycerol fatty acid ester, a glycerin ester, a polyglycerin ester, a sorbitan ester, a propylene glycerol ester, and a sucrose ester.

Examples of the nitrogen-containing nonionic surfactant include an aliphatic alkanol amide, a polyoxyethylene fatty acid amide, and a polyoxyethylene alkyl amide.

Examples of the nonionic surfactant further include a fluorine surfactant and a silicone surfactant.

The total content of the surfactants in the cleaning agent of the invention is preferably from 0.001 g to 10 g, more preferably from 0.01 g to 1 g, and even more preferably from 0.02 g to 0.5 g, with respect to 1 litter of the cleaning agent.

Chelating Agent

The cleaning agent of the present invention may include a chelating agent in addition to DTPA.

Examples of the chelating agent include a precipitate preventing agent for calcium or magnesium such as a general-purpose water softener or an analogous compound thereof. The chelating agent may be used in combination of two or more kinds thereof, if necessary. The adding amount of the chelating agent is not particularly limited as long as the amount is sufficient for sequestering metal ions such as polyvalent metal ions, and is generally from about 5 ppm to about 10,000 ppm with respect to the total amount of the cleaning agent.

Examples of the chelating agent include aminocarboxylic acids, aminocarboxylates, polyaminocarboxylic acids, or polyaminocarboxylates, monoaminopolycarboxylic acids and monoaminopolycarboxylates.

Examples of the aminocarboxylic acid include glycine, L-alanine, β-alanine, L-2-aminobutyric acid, L-norvaline, L-valine, L-leucine, L-norleucine, L-isoleucine, L-alloisoleucine, L-phenylalanine, L-proline, sarcosine, L-ornithine, L-lysine, taurine, L-serine, L-threonine, L-allothreonine, L-homoserine, L-tyrosine, 3,5-diiodo-L-thyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteic acid, L-aspartic acid and L-glutamic acid.

Examples of the polyaminocarboxylic acid include ethylenediaminetetraacetic acid (EDTA). Examples of the monoaminopolycarboxylic acid include N-2-hydroxyethyliminodiacetic acid and L-aspartic acid-N,N-diacetic acid, and ammonium salts and alkali metal salts thereof.

The cleaning agent of the present invention is in a form of an aqueous solution. The cleaning agent of the invention is preferably a solution in which the essential components and, if necessary, other optional component(s) used dissolved in an aqueous solvent. In consideration of effect, water used as the solvent is preferably water free from impurities or deionized water or ultrapure water form which impurities are reduced as low as possible. From the same reason, electrolyzed ion water obtained by electrolysis of water, or hydrogen water obtained by dissolving hydrogen gas in water may be used as the solvent.

pH of Cleaning Agent

The pH of the cleaning agent of the present invention is not particularly limited, and can be appropriately adjusted within the range of from 0.5 to 12 depending on the properties of the device to be cleaned and the type of contaminants to be removed. In order to sufficiently prevent corrosion of a surface to be cleaned (a surface of a substrate for a semiconductor device) and remove metal contamination, the pH is preferably 5 or lower, more preferably from 1 to 5, and even more preferably from 1 to 3.

When the pH is within the above range, adsorption of particles onto a copper metal surface may be suppressed, metal contamination may be sufficiently removed, and corrosion of the copper metal surface may be suppressed.

The pH value may be regulated by adding an organic acid. The organic acid is preferably water-soluble organic salts, and is more preferably organic salts selected from a group consisting of: formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, hydroxyethylimino diacetic acid, imino diacetic acid, and diethylhydroxyl glycine.

The cleaning agent of the present invention may include a conventional pH adjusting agent. In consideration of damages on metals or interlayer dielectric films and of preventing contamination caused by metals included in an inorganic alkali solution, conventional pH adjusting agents such as an acidic pH-adjusting agent containing an inorganic acid (for example, nitric acid or sulfuric acid) and an alkaline pH-adjusting agent containing potassium hydroxide or ammonia are not preferable.

Semiconductor Devices with which the Cleaning Agent is Used

The cleaning agent of the present invention is preferably used for cleaning a substrate for a semiconductor device, on whose surface a metal or metal compound layer and/or wiring of the metal or metal compound are formed, and the substrate has an interlayer dielectric film including SiOC and having a dielectric constant of 3.0 or less. The cleaning agent of the invention is less likely to cause corrosion or oxidation of copper wiring and thus is preferably used in the cleaning of a substrate for semiconductor devices having copper wiring thereon.

When a conventional cleaning agent is used for cleaning a semiconductor device having an interlayer dielectric film which includes SiOC and has a dielectric constant of 3.0 or less, there is a possibility of causing corrosion or retaining organic residues as descried above. On the other hand, since the cleaning agent of the invention contains polycarboxylic acid and DTPA, there is less possibility to cause corrosion or retention of organic residues, and thus it exhibits advantageous effects when used with the semiconductor device having such an interlayer dielectric film.

The semiconductor device with which the cleaning agent of the invention is used has copper wiring and a copper diffusion barrier film on an interlayer dielectric film including SiOC and having a dielectric constant of 3.0 or less.

The dielectric constant of the interlayer dielectric film is calculated based on the capacitance at 1 MHz determined by using a mercury probe (manufactured by Four Dimensions Inc.) and a LCR meter (trade name: HP4285A, manufactured by Yokogawa Hewlett-Packard Company).

The dielectric constant of the interlayer dielectric film is 3.0 or less, and is preferably from 2.8 to 2.0. Since the cleaning agent of the invention can sufficiently prevent corrosion of wiring, the cleaning agent of the invention is also preferably used for a device having a porous low-k interlayer dielectric film (porous low-k film), to which a cleaning agent can easily penetrate.

The interlayer dielectric film is not particularly limited, as long as the film includes SiOC and has a dielectric constant within the above range.

The copper diffusion barrier film on the interlayer dielectric film is a film for preventing copper diffusion and is formed between a conductive film (wiring) consisting of copper or a copper alloy and an interlayer dielectric film.

The material of the barrier film is preferably a low-resistance metal material, and preferably a material containing at least one of tantalum, a tantalum compound, titan, a titan compound, tungsten, a tungsten compound, ruthenium or manganese, more preferably a material containing at least one of TiN, TiW, Ta, TaN, W, WN, Ru or Mn, and even more preferably a material containing at least one of Ta or TaN.

It is preferable to use manganese, which has been prominent in recent years, as a barrier metal. It is known that, by using an alloy of copper and manganese as a material for wiring and by heating the material under certain conditions to precipitate manganese on the surface of the wiring, a thin manganese film having excellent adhesiveness to an adjacent interlayer dielectric film may be formed on the surface of the wiring. Examples of the semiconductor device to be polished with the cleaning agent of the invention also include a semiconductor device on which a barrier layer having such a self-formed manganese layer is formed. The self-formed manganese layer is described in, for example, Journal of Applied Physics 102 (4), 043527 (2007).

The thickness of the barrier film is preferably from about 20 nm to about 30 nm.

The copper wiring is a conductive film consisting of copper or a copper alloy and is formed on the surface of the barrier film so as to fill concave portions of the barrier film.

The cleaning agent of the invention is used for the above-described semiconductor device.

Method for Producing Semiconductor Device

The method for producing a semiconductor device according to the present invention sequentially includes:

forming an interlayer dielectric film including SiOC and having a dielectric constant of 3.0 or less;

forming a copper diffusion barrier film on the interlayer dielectric film;

forming copper wiring on the copper diffusion barrier to form a multilayer structure having wiring thereon;

forming a semiconductor device by chemical mechanical polishing of the surface of the multilayer structure having the wiring thereon with a metal-polishing liquid containing abrasive particles and an oxidizing agent; and

cleaning the surface of the semiconductor device with the cleaning agent for semiconductor devices according to the present invention.

Hereinafter, the cleaning process, which is a specific process in the method for producing the semiconductor device according to the present invention, will be described in more detail.

Cleaning Process

The cleaning process of the method for producing a semiconductor device of the invention uses the above-described cleaning agent of the invention, and is carried out subsequent to the chemical mechanical polishing process (CMP process) in the production of semiconductor devices.

More specifically, copper wiring formed on a semiconductor device is subjected to chemical mechanical polishing with a polishing liquid for metal containing abrasive particles and an oxidizing agent, thereby planarizing the surface of the semiconductor device. Thereafter, the cleaning agent of the invention is applied to the semiconductor surface to clean and remove organic residues, abrasive particles and other contaminants remaining on the surface of the semiconductor device.

In the CMP process, a surface to be polished, such as a surface of a substrate for a semiconductor device, is polished by contacting the surface to be polished with a polishing pad on a polishing platen and by moving them relative to each other, while supplying a polishing liquid to the polishing pad.

In the post-CMP cleaning process, generally the substrate for a semiconductor device after polishing is placed on a spinner, and the cleaning agent of the present invention is supplied to the surface to be polished and a rear surface of the polished substrate at a flow rate of 100 mL/min to 2,000 mL/min, followed by cleaning with brush scrubbing at room temperature for 10 sec to 60 sec.

Cleaning may also be carried out with a commercial cleaning bath. For example, scrub cleaning may be carried out by using a wafer cleaning apparatus (trade name: ZAB8W2W, manufactured by MAT Inc.) with a roll brush (made from PVA) in a scrubbing unit incorporated in the apparatus.

Examples of metal used for a semiconductor device substrate to be polished include W and Cu. In recent years, LSI using Cu that has low wiring resistance has been developed.

Miniaturization of wiring to obtain a high density wiring requires improvements in conductivity and electron migration resistance of copper wiring, and techniques that can achieve high productivity without generating contamination of these highly fine and highly pure materials have also been required.

Examples of the process for cleaning a substrate having a Cu film on the surface thereof, more specifically a substrate having a low-k interlayer dielectric film as an interlayer dielectric film and having copper wiring on the interlayer dielectric film, include a cleaning process conducted after CMP of the Cu film and a cleaning process conducted after forming holes on the interlayer dielectric film by dry-etching. In these cleaning processes, the efficient removal of metal contaminants or particles remaining on the surface of the substrate is particularly important in order to achieve sufficient purity and accuracy of wiring. Consequently, it is preferable to use the cleaning agent of the present invention in these cleaning processes. Furthermore, it is preferable to use the cleaning agent of the present invention since the cleaning agent of the present invention may reduce corrosion or oxidation of copper wiring as described above.

The cleaning agent of the present invention can also be preferably used for the purpose of efficiently removing residues of a passive film-forming agent adsorbed to the surface of copper wiring.

Detection of foreign material on a wafer is required to confirm the effect of removing contaminants in the cleaning process. Examples of apparatus for detecting foreign material include a defect inspection apparatus COMPLUS3 (trade name, manufactured by Applied Materials Inc.) and a defect SEM review observation apparatus (trade name: SEMVISION G3, manufactured by Applied Materials Inc.).

When the production method of a semiconductor device according to the present invention is used, metal contaminants, a substrate material, contaminants of inorganic materials such as polishing dust of an interlayer dielectric film, an organic material such as residues of a passive film-forming agent, and particles such as abrasive particles can be efficiently removed from the surface of a substrate for the semiconductor device in a post-CMP process. In particular, the production method of a semiconductor device according to the present invention is preferably used for cleaning a device in which highly accurate wiring is required, or a device in which efficient removal of contaminants is required in each process of planarization of a multilayer wiring substrate in which an interlayer dielectric film and wiring are newly formed after planarization of a monolayer substrate. Further, the production method of a semiconductor device according to the present invention can reduce corrosion and oxidization of the copper wiring, when a substrate for the semiconductor device has copper wiring.

### EXAMPLES

Hereinafter, the invention will be described with reference to examples, but the invention is not limited to these examples.

Preparation of Polishing Liquid

| | |
|---|---|
| Colloidal silica (abrasive particles: | 5 g/L |
| average particle diameter of 30 nm) | |
| Benzotriazole (BTA) | 1 g/L |
| Glycine | 10 g/L |

Pure water was added to bring the total volume of the polishing liquid to 1000 mL. The pH of the obtained polishing liquid was adjusted to 6.5 with nitric acid and aqueous ammonia.

15 mL/L of 30% hydrogen peroxide (oxidizing agent) was added to the polishing solution just before use.

Polishing of Copper Wafer

Wafer to be Polished

In Example 1, an 8-inch wafer including a silicon substrate with a copper wiring pattern (trade name: SEMATECH 854) and including a low-k film (trade name: Black Diamond (BD), manufactured by Applied Materials Inc.) was used. The low-k film is a porous low-k film and has a dielectric constant of 2.7.

In the following Examples, the interlayer dielectric film used in the wafer of Example 1 was replaced by each of the interlayer dielectric films having physical properties shown in Tables 1 and 3, and evaluated respectively.

Polishing Conditions

Polishing of 8-Inch Wafer

The polishing of each wafer was conducted by using a polishing device LGP-612 (trade name, manufactured by Lapmaster), while supplying the polishing liquid under the following conditions.

Substrate: 8-inch SEMATECH 854, silicon wafer with copper wiring pattern

Number of table rotation: 64 rpm

Number of head rotation: 65 rpm (linear working velocity=1.0 m/s)

Polishing pressure: 140 hPa

Polishing pad: IC-1400 (trade name, manufactured by Rohm and Haas) (K-grv)+(A21)

Polishing liquid supply rate: 200 ml/min

### Example 1

### Preparation of Cleaning Agent

| | |
|---|---|
| Citric acid (organic acid) | 200.0 g/L |
| DTPA (corrosion preventing compound) | 5.0 g/L |
| Dodecyl benzene sulfonic acid (surfactant) | 5.0 g/L |

The above-descried components were mixed to prepare a concentrated cleaning agent (undiluted solution). A cleaning agent of Example 1 was obtained by diluting the concentrated cleaning agent with purified water. The dilution ratio of cleaning agent to purified water was 1 to 40 in mass.

### Examples 2 to 22 and Comparative Examples 1 to 10

Each cleaning agent in Examples 2 to 22 and Comparative Examples 1 to 10 was obtained in a manner similar to Example 1, except that, in preparation of the cleaning agent, the organic acid, the corrosion preventing compound and the surfactant were changed as shown in Table 1 and diluted in a ratio as shown in Table 1.

Cleaning Test

Each silicon substrate having a copper film polished under the conditions described above was subjected to a cleaning test with the respective cleaning agents in Examples 1 to 22 and Comparative Examples 1 to 10 prepared as described above.

The scrub cleaning was carried out using a cleaning apparatus (trade name: ZAB8W2W, manufactured by MAT Inc.) with a roll brush (made from PVA) in a scrubbing unit incorporated into the apparatus. The cleaning agent was supplied for 25 seconds at a rate of 400 mL/min to the upper side of the substrate and at a rate of 400 mL/min to the lower side of the substrate. Subsequently, purified water (deionized water) was supplied for 35 seconds at a rate of 650 mL/min to the upper side of the polishing substrate and at a rate of 500 mL/min to the lower side, followed by treatment for 30 seconds with a spin dryer incorporated into the apparatus.

Evaluation of Performance for Removing Organic Residues and Performance for Preventing Corrosion

The substrates cleaned with the respective cleaning agents of Examples 1 to 22 and Comparative Examples 1 to 10 and dried were evaluated in terms of performance for removing particles and organic residues remaining on the surface of the copper wafer and performance for preventing corrosion. The surface conditions were confirmed with a defect inspection apparatus (trade name: COM PLUS3, manufactured by Applied Materials Inc.), and 100 detected defects were randomly extracted and images of the defects were obtained using a SEM review observation apparatus (trade name: SEM VISION G3, manufactured by Applied Materials Inc.). The defects were classified based on the type of defect (attachment of organic residues or generation of corrosion). The ratio of each defect was determined and the number of defects on the wafer was calculated for each defect. The evaluation was conducted under the following criteria, and the results are shown in Tables 1 to 3.

Evaluation Criteria

### Organic Residues

A: The number of organic residues on the wafer per cm² is less than 0.1.
B: The number of organic residues on the wafer per cm² is 0.1 or more but less than 1.
C: The number of organic residues on the wafer per cm² is 1 or more.

### Corrosion

A: The number of corrosion on the wafer per cm² is less than 0.1.
B: The number of corrosions on the wafer per cm² is 0.1 or more but less than 1.
C: The number of corrosions on the wafer per cm² is 1 or more.

TABLE 1

| | | Example 1 | Example 2 | Example 3 | Example 4 | Example 5 | Example 6 |
|---|---|---|---|---|---|---|---|
| Composition of | Organic acid | Citric acid | Citric acid | Citric acid | Citric acid | Citric acid | Malonic acid |
| cleaning agent | (g/L) | 200.0 | 200.0 | 200.0 | 200.0 | 200.0 | 200.0 |
| | Additive | DTPA | DTPA | DTPA | DTPA | DTPA | DTPA |
| | (g/L) | 5.0 | 2.0 | 5.0 | 5.0 | 5.0 | 2.0 |
| | Surfactant | Dodecyl | Dodecyl | Dodecyl | Alkyl ether | Dodecyl | Dodecyl |
| | (g/L) | benzene | diphenyl ether | benzene | sulfate | sulfonic acid | diphenyl ether |
| | | sulfonic acid | disulfonic acid | sulfonic acid | 5.0 | 5.0 | disulfonic acid |
| | | 1.0 | 1.0 | 5.0 | | | 1.0 |
| | Dilution ratio | 1:40 | 1:40 | 1:40 | 1:40 | 1:40 | 1:40 |
| | (undiluted | | | | | | |
| | solution:purified | | | | | | |
| | water) | | | | | | |
| | pH | 3.1 | 3.1 | 3.1 | 3.1 | 3.1 | 2.4 |
| Semiconductor | Barrier metal | Mn | TaN | Ti | Ti | Mn | Mn |
| device | | self-formed | | | | self-formed | self-formed |
| | k value of porous | 2.7 | 2.7 | 2.4 | 2.4 | 2.4 | 2.4 |
| | low-k film | | | | | | |
| Evaluation | Organic residues | A | A | A | A | A | A |
| | Corrosion | A | A | A | A | A | A |

| | | Example 7 | Example 8 | Example 9 | Example 10 | Example 11 |
|---|---|---|---|---|---|---|
| Composition of | Organic acid | Malonic acid | Maleic acid | Maleic acid | Maleic acid | Maleic acid |
| cleaning agent | (g/L) | 200.0 | 100.0 | 100.0 | 100.0 | 100.0 |
| | Additive | DTPA | DTPA | DTPA | DTPA | DTPA |
| | (g/L) | 5.0 | 5.0 | 5.0 | 5.0 | 5.0 |
| | Surfactant | Polyoxyethylene | Dodecyl | Dodecyl | Alkyl ether | Triisopropyl |
| | (g/L) | lauryl ether | benzene | sulfonic acid | sulfate | naphthalene |
| | | 5.0 | sulfonic acid | 5.0 | 5.0 | sulfonic acid |
| | | | 5.0 | | | 5.0 |
| | Dilution ratio | 1:40 | 1:20 | 1:20 | 1:20 | 1:20 |
| | (undiluted solution:purified | | | | | |
| | water) | | | | | |
| | pH | 2.4 | 2.1 | 2.1 | 2.1 | 2.1 |
| Semiconductor | Barrier metal | Ti | Mn | Mn | TiN | TiN |
| device | | | self-formed | self-formed | | |
| | k value of porous | 2.4 | 2.7 | 2.7 | 2.4 | 2.4 |
| | low-k film | | | | | |
| Evaluation | Organic residues | A | A | A | A | A |
| | Corrosion | A | A | A | A | A |

TABLE 2

| | | Example 12 | Example 13 | Example 14 | Example 15 | Example 16 | Example 17 |
|---|---|---|---|---|---|---|---|
| Composition of | Organic acid | Maleic acid | Maleic acid | Oxalic acid | Oxalic acid | Tartaric acid | Tartaric acid |
| cleaning agent | (g/L) | 100.0 | 100.0 | 100.0 | 100.0 | 100.0 | 100.0 |
| | Additive | DTPA | DTPA | DTPA | DTPA | DTPA | DTPA |
| | (g/L) | 5.0 | 5.0 | 2.0 | 2.0 | 5.0 | 5.0 |
| | Surfactant | Alkyl | Dodecyl | Dodecyl | Dodecyl | Dodecyl | Dodecyl |
| | (g/L) | naphthalene | diphenyl ether | benzene | benzene | benzene | sulfonic acid |
| | | sulfonic acid | disulfonic acid | sulfonic acid | sulfonic acid | sulfonic acid | 3.0 |
| | | 5.0 | 5.0 | 3.0 | 3.0 | 3.0 | |
| | Dilution ratio | 1:20 | 1:20 | 1:20 | 1:20 | 1:20 | 1:20 |
| | (undiluted | | | | | | |
| | solution:purified | | | | | | |
| | water) | | | | | | |
| | pH | 2.1 | 2.1 | 2.4 | 2.4 | 2.8 | 2.8 |
| Semiconductor | Barrier metal | TiN | TiN | Mn | TiN | TaN | TaN |
| device | | | | self-formed | | | |
| | k value of low-k | 2.4 | 2.4 | 2.4 | 2.4 | 2.7 | 2.7 |
| | film | | | | | | |
| Evaluation | Organic residues | A | A | A | A | A | A |
| | Corrosion | A | A | A | A | A | A |

| | | Example 18 | Example 19 | Example 20 | Example 21 | Example 22 |
|---|---|---|---|---|---|---|
| Composition of | Organic acid | Malonic acid | Malic acid | Citric acid | Oxalic acid | Citric acid |
| cleaning agent | (g/L) | 100.0 | 200.0 | 200.0 | 100.0 | 200.0 |
| | Additive | DTPA | DTPA | DTPA | DTPA | DTPA |
| | (g/L) | 5.0 | 3.0 | 3.0 | 3.0 | 5.0 |
| | Surfactant | Dodecyl benzene | Dodecyl benzene | Dodecyl benzene | Dodecyl benzene | Dodecyl benzene |
| | (g/L) | sulfonic acid | sulfonic acid/ | sulfonic acid | sulfonic acid | sulfonic acid |
| | | 3.0 | polyoxyethylene | 3.0 | 3.0 | 1.0 |
| | | | lauryl ether | | | |
| | | | 3.0/3.0 | | | |
| | Dilution ratio | 1:40 | 1:40 | 1:40 | 1:40 | 1:40 |
| | (undiluted | | | | | |
| | solution:purified | | | | | |
| | water) | | | | | |
| | pH | 2.6 | 3.0 | 3.3 | 2.7 | 3.1 |
| Semiconductor | Barrier metal | TaN | Mn | Ru | Ru | Mn |
| device | | | self-formed | | | self-formed |
| | k value of low-k | 2.7 | 2.7 | 2.5 | 2.7 | 2.8 |
| | film | (Porous) | (Porous) | (Porous) | (Porous) | |
| Evaluation | Organic residues | A | A | A | A | A |
| | Corrosion | A | A | A | A | A |

TABLE 3

| | | Comparative | Comparative | Comparative | Comparative | Comparative |
|---|---|---|---|---|---|---|
| | | Example 1 | Example 2 | Example 3 | Example 4 | Example 5 |
| Composition of | Organic acid | TMAH | TEAH | Malic acid | Citric acid | Lactic acid |
| cleaning agent | (g/L) | 20.0 | 25.0 | 200.0 | 200.0 | 50.0 |
| | Additive | DTPA | DTPA | EDTA | Cy-DTA | none |
| | (g/L) | 5.0 | 2.0 | 1.0 | 2.0 | — |
| | Surfactant | Dodecyl | Dodecyl | Dodecyl | Dodecyl | Dodecyl |
| | (g/L) | benzene | diphenyl ether | benzene | benzene | benzene |
| | | sulfonic acid | disulfonic acid | sulfonic acid | sulfonic acid | sulfonic acid |
| | | 1.0 | 2.0 | 3.0 | 3.0 | 3.0 |
| | Dilution ratio | 1:40 | 1:40 | 1:40 | 1:40 | 1:40 |
| | (undiluted | | | | | |
| | solution:purified | | | | | |
| | water) | | | | | |
| | pH | 9.5 | 11.5 | 3.0 | 3.3 | 2.6 |
| Semiconductor | Barrier metal | Mn | TaN | Mn | Ru | TaN |
| device | | self-formed | | self-formed | | |
| | k value of porous | 2.4 | 2.7 | 2.7 | 2.5 | 2.4 |
| | low-k film | (Porous) | (Porous) | (Porous) | | |
| Evaluation | Organic residues | B | C | A | A | B |
| | Corrosion | B | C | C | C | C |
| | | Comparative | Comparative | Comparative | Comparative | Comparative |
| | | Example 6 | Example 7 | Example 8 | Example 9 | Example 10 |
| Composition of | Organic acid | Malonic acid | Maleic acid | Citric acid | Citric acid | Oxalic acid |
| cleaning agent | (g/L) | 200.0 | 100.0 | 200.0 | 200.0 | 200.0 |
| | Additive | DTPA | DTPA | BTA | none | none |
| | (g/L) | 5.0 | 5.0 | 5.0 | — | — |
| | Surfactant | none | none | Dodecyl | Dodecyl | Dodecyl |
| | (g/L) | — | — | benzene | benzene | benzene |
| | | | | sulfonic acid | sulfonic acid | sulfonic acid |
| | | | | 3.0 | 3.0 | 3.0 |
| | Dilution ratio | 1:40 | 1:20 | 1:40 | 1:40 | 1:40 |
| | (undiluted | | | | | |
| | solution:purified | | | | | |
| | water) | | | | | |
| | pH | 2.4 | 2.1 | 3.1 | 3.3 | 2.4 |
| Semiconductor | Barrier metal | Ti | Mn | Mn | Mn | TiN |
| device | | | self-formed | self-formed | self-formed | |
| | k value of porous | 2.4 | 2.7 | 2.4 | 2.4 | 2.4 |
| | low-k film | | | | | |
| Evaluation | Organic residues | B | B | C | A | B |
| | Corrosion | C | C | A | C | C |

Cy-DTA: cyclohexanediaminetetraacetic acid

In Tables 1 to 3, the ratio of undiluted solution to purified water in “Dilution ratio” is based on mass.

As is evident from Tables 1 to 3, when the cleaning agents of Examples 1 to 22 were used for cleaning of the substrate in the post-CMP process, the organic residues attached on the substrate were effectively cleaned and removed while corrosion of wiring on the substrate was prevented.

On the other hand, when the cleaning agents of Comparative Examples 1 and 2, each of which does not contain polycarboxylic acid, were used for cleaning, performance for removing organic residues was not sufficient compared with the cleaning agents of Examples 1 to 22. Furthermore, when the cleaning agents of Comparative Examples 3 to 5, each of which does not contain DTPA, were used for cleaning, corrosion was caused. In Comparative Example 8 where BTA was used as an additive, while corrosion was suppressed, performance for removing organic residues was not sufficient compared with the cleaning agents of Examples 1 to 22.

Therefore, it is found that the cleaning agents in Examples 1 to 22 exhibit excellent cleaning performance, while preventing corrosion of copper wiring on the copper wafer.

Test for Stability Over Time

The temporal stability of the respective cleaning agents of Examples 1 to 5 and Examples 8 to 13 was tested one week after preparation. The respective cleaning agents were stored for 7 days at a temperature of 25° C. under 50% humidity, and precipitation in the cleaning agents generated during storage was visually confirmed. The stability over time was evaluated under the following criteria. The results are shown in Table 4.

Evaluation Criteria

A: Precipitation was not visually confirmed.
B: Slight precipitation was confirmed, but was practically not problematic.

TABLE 4

| | | Example 1 | Example 2 | Example 3 | Example 4 | Example 5 |
|---|---|---|---|---|---|---|
| Composition of | Organic acid | Citric acid | Citric acid | Citric acid | Citric acid | Citric acid |
| cleaning agent | (g/L) | 200.0 | 200.0 | 200.0 | 200.0 | 200.0 |
| | Additive | DTPA | DTPA | DTPA | DTPA | DTPA |
| | (g/L) | 5.0 | 2.0 | 5.0 | 5.0 | 5.0 |
| | Surfactant | Dodecyl | Dodecyl | Dodecyl | Alkyl ether | Dodecyl |
| | (g/L) | benzene | diphenyl ether | benzene | sulfate | sulfonic acid |
| | | sulfonic acid | disulfonic acid | sulfonic acid | 5.0 | 5.0 |
| | | 1.0 | 1.0 | 5.0 | | |
| | Dilution ratio | 1:40 | 1:40 | 1:40 | 1:40 | 1:40 |
| | (undiluted solution:purified | | | | | |
| | water) | | | | | |
| | pH | 3.1 | 3.1 | 3.1 | 3.1 | 3.1 |
| Semiconductor | Barrier metal | Mn | TaN | Ti | Ti | Mn |
| device | | self-formed | | | | self-formed |
| | k value of porous | 2.7 | 2.7 | 2.4 | 2.4 | 2.4 |
| | low-k film | | | | | |
| Evaluation | precipitation | A | B | A | A | A |

| | | Example 8 | Example 9 | Example 10 | Example 11 | Example 12 | Example 13 |
|---|---|---|---|---|---|---|---|
| Composition | Organic acid | Maleic acid | Maleic acid | Maleic acid | Maleic acid | Maleic acid | Maleic acid |
| of cleaning | (g/L) | 100.0 | 100.0 | 100.0 | 100.0 | 100.0 | 100.0 |
| agent | Additive | DTPA | DTPA | DTPA | DTPA | DTPA | DTPA |
| | (g/L) | 5.0 | 5.0 | 5.0 | 5.0 | 5.0 | 5.0 |
| | Surfactant | Dodecyl | Dodecyl | Alkyl ether | Triisopropyl | Alkyl | Dodecyl |
| | (g/L) | benzene | sulfonic acid | sulfate | naphthalene | naphthalene | diphenyl ether |
| | | sulfonic acid | 5.0 | 5.0 | sulfonic acid | sulfonic acid | disulfonic acid |
| | | 5.0 | | | 5.0 | 5.0 | 5.0 |
| | Dilution ratio | 1:20 | 1:20 | 1:20 | 1:20 | 1:20 | 1:20 |
| | (undiluted | | | | | | |
| | solution:purified | | | | | | |
| | water) | | | | | | |
| | pH | 2.1 | 2.1 | 2.1 | 2.1 | 2.1 | 2.1 |
| Semiconductor | Barrier metal | Mn | Mn | TiN | TiN | TiN | TiN |
| device | | self-formed | self-formed | | | | |
| | k value of porous | 2.7 | 2.7 | 2.4 | 2.4 | 2.4 | 2.4 |
| | low-k film | | | | | | |
| Evaluation | precipitation | A | A | A | B | B | B |

From the results in Table 4, it is found that precipitation of solids in the cleaning agents was suppressed even after storage for one week and that the cleaning agents of the present invention have excellent stability over time.

All publications, patent applications, and technical standards mentioned in this specification are herein incorporated by reference to the same extent as if each individual publication, patent application, or technical standard was specifically and individually indicated to be incorporated by reference.

What is claimed is:

1. A cleaning agent used after chemical mechanical polishing of a semiconductor device, the cleaning agent comprising a polycarboxylic acid and diethylenetriamine pentaacetic acid, the semiconductor device including a copper diffusion barrier film and copper wiring on an interlayer dielectric film, and the dielectric film containing SiOC and having a dielectric constant of 3.0 or less.

2. The cleaning agent according to claim 1, wherein the content of the polycarboxylic acid in the cleaning agent is from 0.05 g/L to 300 g/L with respect to the total mass of the cleaning agent.

3. The cleaning agent according to claim 1, wherein the content of the diethylenetriamine pentaacetic acid in the cleaning agent is from 0.00001 g/L to 50 g/L with respect to the total mass of the cleaning agent.

4. The cleaning agent according to claim 1, wherein the copper diffusion barrier film comprises manganese.

5. The cleaning agent according to claim 4, wherein the copper diffusion barrier film comprises a self-formed manganese layer.

6. The cleaning agent according to claim 1, wherein the copper diffusion barrier film comprises at least one selected from Ti, TiN, Ta, TaN or Ru.

7. The cleaning agent according to claim 1, wherein the polycarboxylic acid is at least one selected from the group consisting of oxalic acid, citric acid, maleic acid, malic acid and tartaric acid.

8. The cleaning agent according to claim 1, which has a pH value of 1 to 5.

9. The cleaning agent according to claim 1, further including at least one surfactant selected from an anionic surfactant or a nonionic surfactant.

10. A method for producing a semiconductor device comprising:
forming an interlayer dielectric film containing SiOC and having a dielectric constant of 3.0 or less;
forming a copper diffusion barrier film on the interlayer dielectric film;
forming copper wiring on the copper diffusion barrier film to form a multilayer structure having the wiring thereon;
forming a semiconductor device by chemical mechanical polishing of the surface of the multilayer structure having the wiring thereon with a metal-polishing liquid containing abrasive particles and an oxidizing agent; and
cleaning the surface of the semiconductor device with the cleaning agent of claim 1.

11. A method for producing a semiconductor device comprising:
forming an interlayer dielectric film containing SiOC and having a dielectric constant of 3.0 or less;
forming wiring containing copper and manganese on the interlayer dielectric film;
heating the wiring containing copper and manganese to accumulate the manganese at a surface of the wiring and forming a self-formed manganese layer, thereby forming a multilayer structure having a copper diffusion barrier film thereon;
forming a semiconductor device by chemical mechanical polishing of the surface of the multilayer structure having a copper diffusion barrier film thereon with a metal-polishing liquid containing abrasive particles and an oxidizing agent; and
cleaning the surface of the semiconductor device with the cleaning agent of claim 1.
